(19) United States
(12) Patent Application Publication
(10) Pub. No.: US 2006/0075760 A1
(43) Pub. Date: Apr. 13, 2006

(54) Temperature measuring device using a matrix switch, a semiconductor package and a cooling system

(76) Inventors: Yun-Hyeok Im, Gyeonggi-do (KR); Suk-Chae Kang, Gyeonggi-do (KR); Hee-Seok Lee, Gyeonggi-do (KR)

Correspondence Address: MARGER JOHNSON & McCOLLOM, P.C., 1030 S.W. Morrison Street, Portland, OR, 97205, US

(21) Appl. No.: 11/217,597

(22) Filed: Aug. 31, 2005

(30) Foreign Application Priority Data
Oct. 12, 2004 (KR) 2004-81309

(51) Int. Cl. F25B 21/02; F25D 23/12; H01L 35/28; F24F 7/00

(52) U.S. Cl. 62/3.7; 62/259.2; 136/204; 236/49.3

(57) ABSTRACT

An embodiment relates to a temperature measuring device using a matrix switch, and a semiconductor package. In another embodiment a cooling system may be included. A plurality of temperature sensors may be arranged on a surface of a semiconductor device. The matrix switch may select the temperature sensors by an address method to form a circuit that includes the selected temperature sensor. A measuring unit may receive an output signal of the selected temperature sensor to calculate the temperature at the selected temperature sensor.

### CROSS REFERENCE TO RELATED APPLICATIONS

This U.S. non-provisional application claims benefit of priority under 35 U.S.C. §119 of Korean Patent Application No. 2004-81309, filed on Oct. 12, 2004, the entire contents of which are incorporated herein by reference.

### BACKGROUND OF THE INVENTION

1. Field of the Invention

The present invention relates to a semiconductor device and, more particularly, to a temperature measuring device using a matrix switch, a semiconductor package and a cooling system.

2. Description of the Related Art

High performance semiconductor packages operate with high power consumption. Newer, higher performing semiconductor packages use even more power. This increased operating power generates heat, which, if not properly dissipated, may result in damage to the semiconductor packages.

To dissipate the heat which may occur during operation of a semiconductor chip, semiconductor devices such as microprocessors, memory devices, and power devices may be specifically designed for radiating heat. For example, a heat sink or a fan may be installed in a semiconductor package.

Properly designing for heat dissipation may require measuring the temperature distribution of the surface of a semiconductor chip. Conventionally, a heat sink or a fan has been installed regardless of the temperature distribution of the surface of a semiconductor chip. In the case of microprocessors, heat may concentrate on a partial area of the semiconductor chip, generating a hot spot. The heat sink or fan used may be insufficient for effectively preventing the hot spot.

The operating temperature of a wafer may be one of several parameters influencing the surface structure of its materials and the deposition or etching details of a thin film. In addition to the temperature of a wafer, thermal uniformity may be required for a stable semiconductor manufacturing process.

To check the thermal uniformity in a process chamber, an indirect temperature measuring method may be currently used in the semiconductor field. The indirect temperature measuring method may measure the temperature of a wafer using a change in its thin film characteristics, such as its electrical properties, after a specific semiconductor manufacturing process is completed. This method may not estimate the temperature of a wafer during a desired process, but only the maximum temperature after the process.

To solve this problem, a device for directly measuring the temperature of a wafer in a process chamber is disclosed in Japanese Laid-Open Patent No. 10-62263, U.S. Pat. No. 5,969,639 and Korean Laid-Open Patent No. 2004-3539.

Devices for measuring the surface temperature of a wafer include thermocouples, thermistors, and resistive thermal detectors (RTD). The thermocouple may use the Seebeck Effect. In the Seebeck Effect, two dissimilar metals form a circuit loop, one metal makes up one part of the loop, and the other metal makes up the other part. A high temperature is applied to one of the metals and a lower temperature is applied to the other metal. A voltage difference between different parts of the circuit loop will be generated due to the temperature differences of the different metals. A data acquisition system may be connected to this circuit loop to measure this voltage difference, and thus the temperature at a desired area of a wafer may be measured.

The Japanese Laid-Open Patent No. 10-62263 shows a plurality of Cu wires and a plurality of Cu—Ni wires formed on a wafer, to be used to measure temperature. The Cu—Ni wires may be formed perpendicular to the Cu wires. One end of each of the Cu wires and Cu—Ni wires may be connected to voltage measuring devices. These voltmeters may measure the potential difference of the thermoelectromotive force occurring between contacts of the Cu wires and the Cu—Ni wires, thereby measuring the surface temperature of a wafer. The contacts of the Cu wires and Cu—Ni wires may serve as thermocouples.

To precisely measure the temperature at a contact of a specific Cu wire and a specific Cu—Ni wire, a closed circuit loop should be formed at the contact of the specific Cu and Cu—Ni wires. However, the device of this Japanese prior art may have a many contacts electrically connected to each other. Thus it is difficult to precisely measure the temperature at a specific contact due to adjacent contacts.

U.S. Pat. No. 5,969,639 discloses an apparatus for directly measuring the surface temperature of a wafer using a plurality of temperature sensors, such as thermocouples, thermistors, and RTDs that are hard-wired on the wafer.

The apparatus of the U.S. prior art has disadvantages. For example, as the number of the temperature sensors increases, the hard wire connections become more complicated, and the hard wires are more apt to breakage. In practice, it is not practical to form hard wires over the entire surface of a wafer. Thus, it is difficult to precisely measure the temperature of the entire surface of the wafer or a semiconductor chip. Furthermore, the hard wires used may serve as a cold finger, whereby the measured temperature may be lower than the actual temperature.

The Korean Laid-Open Patent No. 2004-3539 discloses a thin film type temperature sensor. A thin film may be formed on a silicon wafer using dissimilar metals, for example a first metal and a second metal. One end of the first metal pattern may be connected to one end of the second metal pattern to form a contact portion. The other end of each of the first and second metal patterns may be non-contacting and forming a wiring portion. The wiring portion of the first and second metals may be connected to form a closed loop. In this manner, the temperature at the contact may be measured.

The apparatus of the Korean prior art may have a wiring portion which may be complicated and occupy a larger area than the contact portion. Consequently, the contact portion may be limited to certain positions and areas. Thus it is difficult to measure the temperature of the entire surface of the wafer and a semiconductor chip.

### SUMMARY OF THE INVENTION

An exemplary embodiment of the present invention is directed to precisely measuring temperatures of as much as the entire surface of a semiconductor or other device.

Another exemplary embodiment of the present invention is directed to effectively measuring temperatures without forming complicated wiring on the surface of a semiconductor or other device.

Another exemplary embodiment of the present invention is directed to applying a temperature sensor to a semiconductor chip unit.

Another exemplary embodiment of the present invention is directed to providing a cooling system for a semiconductor package using information about the surface temperatures of the semiconductor package.

According to an exemplary embodiment of the present invention, a temperature measuring device may have temperature sensors and a matrix switch. The temperature sensors may be uniformly arranged over the entire surface of a semiconductor device. The matrix switch may select the temperature sensors in an address method and form a closed loop at the selected temperature sensor to output an output signal of the selected temperature sensor.

The measuring unit may be a data acquisition system and may be installed inside or outside a semiconductor device.

The semiconductor device may include a semiconductor chip or a wafer.

According to an exemplary embodiment of the present invention, a cooling system for a semiconductor package may comprise a semiconductor package, a measuring unit, and a controller. The measuring unit may receive an output signal of a specific temperature sensor selected by a matrix switch to calculate the temperature at the temperature sensor. The cooling system may further comprise a cooling means for receiving a signal from the controller to cool the semiconductor package.

### BRIEF DESCRIPTION OF THE DRAWINGS

The exemplary embodiments of the present invention will be readily understood with reference to the following detailed description thereof provided in conjunction with the accompanying drawings, wherein like reference numerals designate like structural elements.

FIG. 1 is a block diagram of a temperature measuring device in accordance with an exemplary, non-limiting embodiment of the present invention.

FIG. 2 is a schematic plan view of a temperature sensor of a temperature measuring device in accordance with an exemplary, non-limiting embodiment of the present invention.

FIG. 3 is a cross-sectional view of the temperature sensor of FIG. 2.

FIG. 4 is an enlarged circuit diagram of section A of FIG. 2.

FIG. 5 is a block diagram of an example of a cooling system for a semiconductor package in accordance with an exemplary, non-limiting embodiment of the present invention.

FIG. 6 is a block diagram of another example of a cooling system for a semiconductor package in accordance with an exemplary, non-limiting embodiment of the present invention.

These drawings are provided for illustrative purposes only and are not drawn to scale. The spatial relationships and relative sizing of the elements illustrated in the various embodiments may have been reduced, expanded or rearranged to improve the clarity of the figure with respect to the corresponding description. The figures, therefore, should not be interpreted as accurately reflecting the relative sizing or positioning of the corresponding structural elements that could be encompassed by an actual device manufactured according to the exemplary embodiments of the invention.

### DETAILED DESCRIPTION OF THE EXEMPLARY EMBODIMENTS

Exemplary, non-limiting embodiments of the present invention will now be described more fully hereinafter with reference to the accompanying drawings. This invention may, however, be embodied in many different forms and should not be construed as limited to the exemplary embodiments set forth herein. Rather, the disclosed embodiments are provided so that this disclosure will be thorough and complete, and will fully convey the scope of the invention to those skilled in the art. The principles and feature of this invention may be employed in varied and numerous embodiments without departing from the scope of the invention.

It should be noted that these figures are intended to illustrate the general characteristics of methods and devices of exemplary embodiments of this invention, for the purpose of the description of such exemplary embodiments herein. These drawings are not, however, to scale and may not precisely reflect the characteristics of any given embodiment, and should not be interpreted as defining or limiting the range of values or properties of exemplary embodiments within the scope of this invention. Rather, for simplicity and clarity of illustration, the dimensions of some of the elements are exaggerated relative to other elements.

Furthermore, well-known structures and processes are not described or illustrated in detail to avoid obscuring the present invention. Like reference numerals are used for like and corresponding parts of the various drawings.

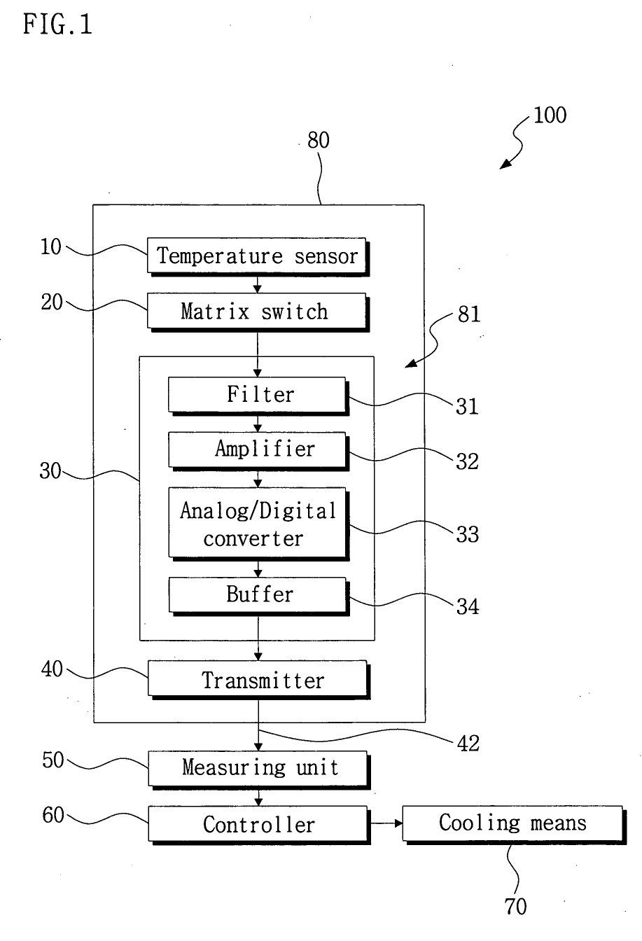

FIG. 1 is a block diagram of a temperature measuring device 100 in accordance with an exemplary, non-limiting embodiment of the present invention.

Referring to FIG. 1, the temperature measuring device 100 may comprise a semiconductor device 80, a temperature sensing unit 81, and a measuring unit 50. The temperature sensing unit 81 may be formed on the surface of the semiconductor device 80 and be able to sense the temperature changes of the surface of the semiconductor device 80. The measuring unit 50 may calculate the temperature change of the surface of the semiconductor chip 80 using an output signal output from the temperature sensing unit 81. The semiconductor device 80 may include a wafer, a semiconductor chip, or any device required for a high density of temperature measurements.

The temperature sensing unit 81 may include a plurality of temperature sensors 10, a matrix switch 20, and a signal transmitter 40. The temperature sensors 10 may be arranged uniformly over the surface of the semiconductor device 80. The matrix switch 20 may select the temperature sensors 10 by an address method and form a closed loop at the selected temperature sensor 10 to output an output signal of the temperature sensor 10. The signal transmitter 40 may transmit the output signal of the selected temperature sensor 10 to the measuring unit 50. The measuring unit 50 may calculate the surface temperature at the temperature sensor 10 using the output signal transmitted by the transmitter 40.

The temperature sensing unit 81 may further include a signal post-processing unit 30. The signal post-processing unit 30 may convert the output signal of a specific temperature sensor 10 to an output signal perceivable by the measuring unit 50. The signal post-processing unit 30 may transmit the converted output signal to the transmitter 40. Since the electromotive force caused by heat occurring at the temperature sensor 10 is a relatively low voltage, for example several mV, the signal post-processing unit 30 may remove noise from the output signal of the temperature sensor 10 and convert it to an output signal perceivable by the measuring unit 50. In other words, the temperature sensors 10 may each have an address. The address signal may be input to a desired temperature sensor 10 through the matrix switch 20. The electromotive force (the output signal) occurring at the temperature sensor 10 of a corresponding address may be transmitted to the signal post-processing unit 30.

The signal post-processing unit 30 may include a filter 31, an amplifier 32, an analog/digital converter 33, and a buffer 34. The filter 31 may remove noise from the output signal transmitted from the temperature sensor 10. The amplifier 32 may amplify the signal passed through the filter 31. The analog/digital converter 33 may convert the output signal passed through the amplifier 32 from, for example, an analog signal to a digital signal. The buffer 34 may compensate for any differences in time or speed of the signal flow which may occur with transmitting the digital signal to the measuring unit 50.

The transmitter 40 may transmit the output signal to the measuring unit 50 via a wire or a wireless communication network 42.

The measuring unit 50 may be a data acquisition system able to calculate temperatures from the output signal transmitted by the transmitter 40. The calculated temperatures may show the temperature distribution of the entire surface of the semiconductor device 80, and also the temperature at a specific temperature sensor 10. Although the exemplary embodiment of the present invention shows the measuring unit 50 installed outside the semiconductor device 80, the measuring unit 50 may be installed inside the semiconductor device 80.

Information about the surface temperatures of the semiconductor device 80 calculated by the measuring unit 50 may be transmitted to a controller 60. The controller 60 may operate a cooling system 70 to control temperatures suitable for the manufacture or operation of the semiconductor device 80. For example, if the semiconductor device 80 is a wafer inserted into a process chamber of the semiconductor manufacturing process, the controller 60 may operate the cooling system 70 to uniformly maintain the surface temperature of the wafer. If the semiconductor device 80 is a semiconductor chip embedded in a semiconductor package, the controller 60 may operate a cooling means of the cooling system 70 to improve the heat radiation of the semiconductor package.

The controller 60 may process the temperature information and provide the temperature distribution of the entire surface of the semiconductor device 80 as a numerical value or a graphical output. The processed information may be observed via a display.

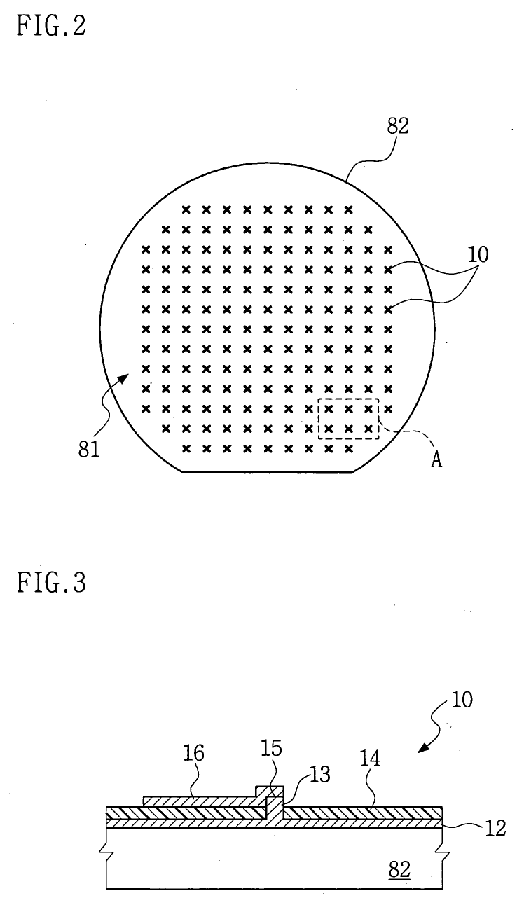

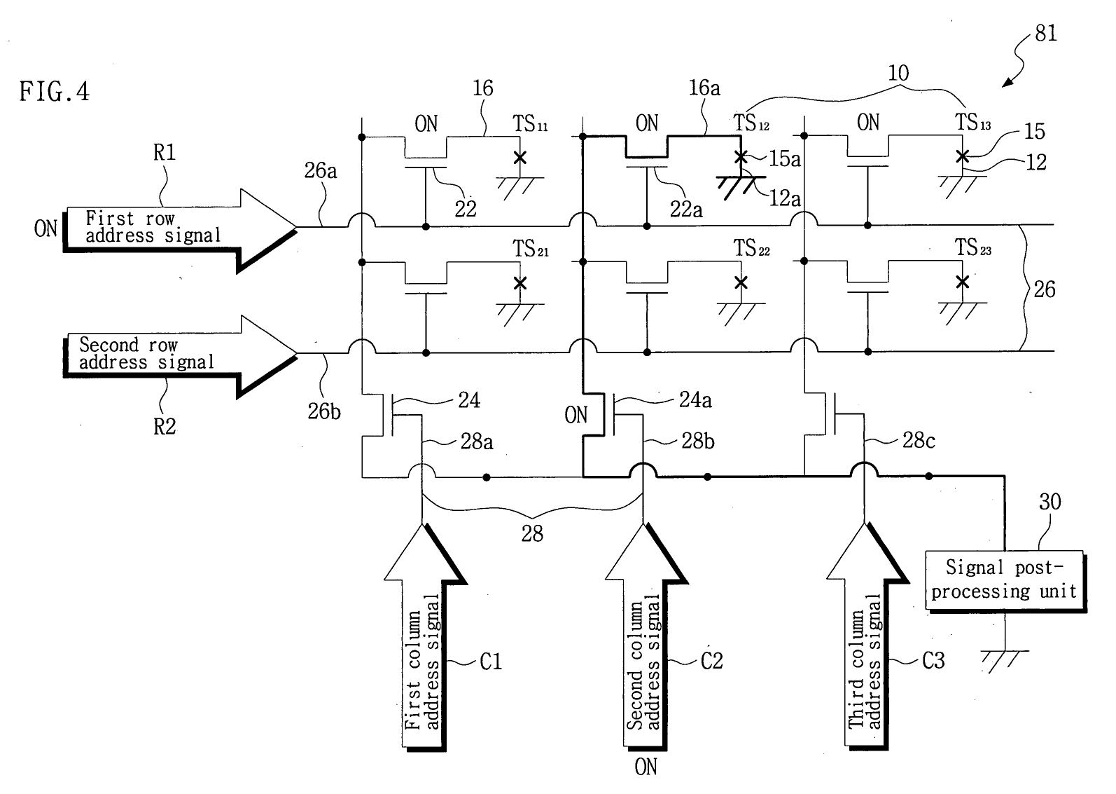

The temperature sensing unit 81 may be described with reference to FIGS. 2 through 4. FIG. 2 is a schematic plan view of temperature sensors 10 in accordance with an exemplary, non-limiting embodiment of the present invention. FIG. 3 is a cross-sectional view of the temperature sensors 10 of FIG. 2. FIG. 4 is an enlarged circuit diagram of section A of FIG. 2. Although the exemplary embodiment of the present invention shows the temperature sensing unit 81 formed on a wafer 82, the temperature sensing unit 81 may be formed on the surface of a semiconductor chip with the same structure.

Referring to FIGS. 2 through 4, the temperature sensors 10 may be arranged in rows and columns on the surface of the wafer 82. The temperature sensors 10 may be formed with a high density using a semiconductor manufacturing process. The temperature sensors 10 may include a first metal wiring 12, an insulating layer 14, and a second metal wiring 16. The first metal wiring 12 may be formed on the surface of the wafer 82. The first metal wiring 12 may be grounded and have a connection projection 13. The insulating layer 14 may be formed on the first metal wiring 12 so that the top of the connection projection 13 may be exposed. One end of the second metal wiring 16 may be connected to the connection projection 13 to form a contact 15. The other end of the second metal wiring 16 may be connected to the signal post-processing unit 30 through the matrix switch 20. The second metal wiring 16 may be opened and closed by the matrix switch 20. The first and second metal wirings 12 and 16 may be formed using a sputtering method, which is well-known in the art of semiconductor manufacturing. The insulating layer 14 may be formed using a chemical vapor deposition method, which is also well-known in the art of semiconductor manufacturing.

Each temperature sensor 10 may be a thermocouple using the Seebeck Effect. Each temperature sensor 10 may measure the electromotive force due to the temperature change at the contact 15 of the first and second wirings 12 and 16 to measure the surface temperature at the contact 15. The first metal wiring 12 and the second metal wiring 16 may be formed from different metals. Preferably, the first and second metal wirings 12 and 16 may be formed of different metals having a relatively large difference in their Seebeck coefficients. For example, the metals may include alumel and chromel of K-type or constantan and copper of T-type.

The matrix switch 20 may have row switches 22 and column switches 24. The row and column switches 22 and 24 may be connected to row address lines 26 and column address lines 28, respectively, corresponding to the arrangement of the temperature sensors 10 to select the temperature sensors 10 by an address method. The row switches 22 may be formed at the temperature sensors 10 of the row address lines 26. The row switches 22 may be opened and closed simultaneously by the row address signal, and the column switches 24 may be opened and closed by the column address signal. The row and column switches 22 and 24 may be transistors that are turned on and off responsive to a signal to their respective gates. Each column switch 24 may output the output signal of each temperature sensor 10 of a corresponding column where the column address signal is input among the temperature sensors 10 of a corresponding row where the row address signal has been input, to the signal post-processing unit 30. In other words, the column switch 24 may output the output signal of the contact 15 of each temperature sensor 10 located at the intersection of the row and column switches 22 and 24, to the signal post-processing unit 30.

As shown in FIG. 4, address signals may be input to a first row address line 26a and a second column address line 28b, as an example, so that a temperature sensor TS12 may be selected by a first row switch 22a and a second column switch 24a. First and second metal wirings 12a and 16a of the temperature sensor TS12 may be connected to form a closed loop. The electromotive force caused by heat occurring at a contact 15a of the temperature sensor TS12 may be transmitted to the signal post-processing unit 30.

In this manner, the heat occurring at the contacts 15 of the temperature sensors 10 may be measured, thereby precisely measuring the temperature of the entire surface of the wafer 82. Furthermore, the temperature sensors 10 may be formed with a high density on the surface of the wafer 82 by a semiconductor fabricating process, thereby improving the measurement of the surface temperature of the wafer 82.

The address method may be similar to a method for storing/reading information in a memory cell, but the address method may have a temperature sensor 10 instead of a capacitor.

Therefore, the present invention may precisely measure the surface temperatures of the wafer 82 using the temperature sensors 10 formed with a high density on the wafer surface, while eliminating the need for complicated metal wirings on the wafer.

Furthermore, the temperature measuring device of the present invention may directly measure the surface temperatures of the wafer 82 in a process chamber during a process. Therefore, the temperature measuring device may control internal temperatures of the process chamber based on the measured surface temperatures of the wafer 82. The temperature measuring device may then uniformly maintain the surface temperatures of the wafer 82.

A cooling system for a semiconductor package may be incorporated using information about the surface temperatures of the semiconductor device.

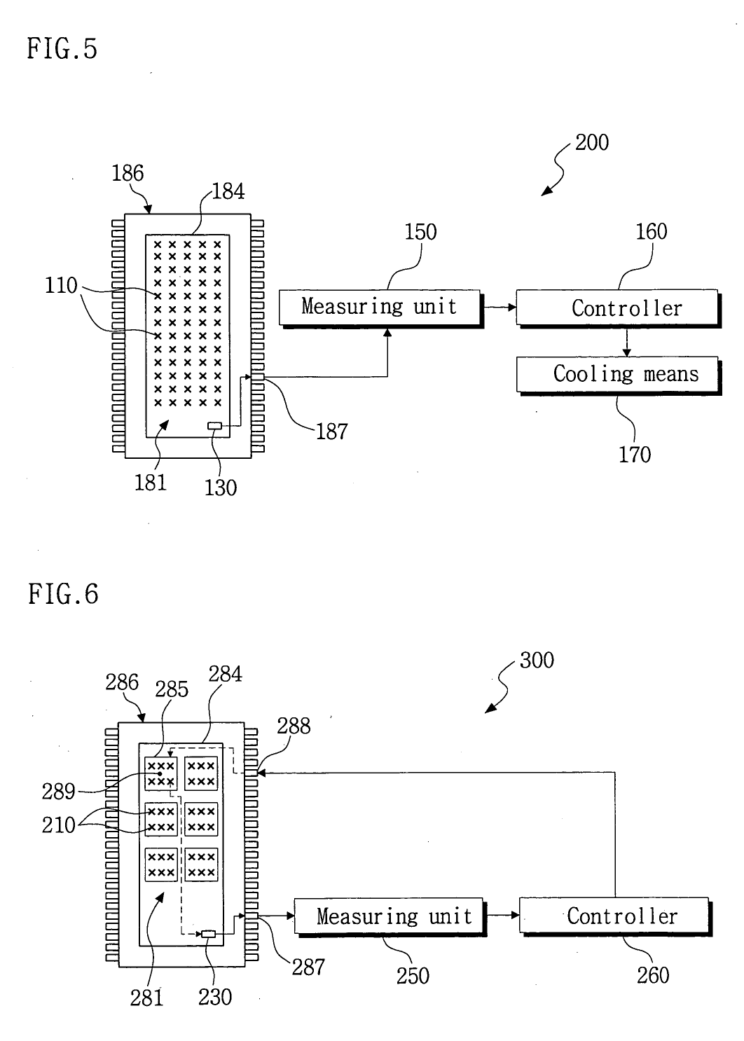

FIG. 5 is a block diagram of an example of a cooling system 200 for a semiconductor package in accordance with an exemplary, non-limiting embodiment of the present invention.

Referring to FIG. 5, the cooling system 200 may comprise a semiconductor package 186 having a semiconductor chip 184, a measuring unit 150, a controller 160, and a cooling means 170. The semiconductor chip 184 may have a temperature sensor 110, a matrix switch (not shown), and a temperature sensing unit 181 including a signal post-processing unit 130. The temperature sensor 110 may measure the surface temperature of the semiconductor chip 184 during operation. An external connection terminal 187 (hereinafter referred to as a temperature output terminal) connected to the signal post-processing unit 130 among other external connection terminals of the semiconductor package 186 may be connected to the measuring unit 150. The measuring unit 150 may transmit a signal transmitted from the signal post-processing unit 130 to the controller 160. The controller 160 may operate the cooling means 170 according to the surface temperatures of the semiconductor chip 184 to cool its surface.

The cooling means 170 may be, but it is not limited to, a fan. Conventionally, a heat sink or a cooling means may be installed in a semiconductor package. The heat sink or cooling means may be insufficient to effectively respond to a hot spot. However, a temperature sensing unit of the present invention may recognize the location of the hot spot. Therefore, the cooling system 200 may reduce the likelihood of a decline in performance of the semiconductor package due to the hot spot.

FIG. 6 is a block diagram of another example of a cooling system 300 for a semiconductor package in accordance with an exemplary, non-limiting embodiment of the present invention.

Referring to FIG. 6, the cooling system 300 may comprise a semiconductor package 286 having a semiconductor chip 284, a measuring unit 250, and a controller 260. The semiconductor chip 284 may have a temperature sensing unit 281. The cooling system 300 may further comprise a cooling means.

The measuring unit 250 may transmit a signal transmitted from a signal post-processing unit 230 through a temperature output terminal 287 to the controller 260. The controller 260 may switch a cell area 285 of the semiconductor chip 284. The temperature sensing unit 281 may comprise sensor groups 289 that further comprise temperature sensors 210. In an embodiment, sensor groups 289 may correspond to respective cell areas 285. If a hot spot occurs in a specific cell area 285, for example, then the corresponding sensor group 289 will detect this. Consequently, the specific over-heated cell area 285 of the semiconductor chip 284 may be placed into a sleep mode according to its surface temperature. In a sleep mode, less power is provided to the semiconductor chip 284, and thus it will begin to cool upon entering this mode. Therefore, the likelihood of a decline in performance, or failure, of a package due to the hot spot may be prevented.

The controller 260 may input a sleep-mode signal to the semiconductor package 286 through a sleep-mode terminal 288 of an external connection terminal. The circuit may be designed such that the switch to a sleep mode may be made within the semiconductor chip 284.

A general review of some of the features of the embodiments already discussed, as well as some new features, will now proceed.

Generally, a hot spot may occur according to the type of fabricated semiconductor chip. A temperature measuring device of an embodiment of the present invention may indicate the location of a hot spot. Information on the location of a hot spot may be fed back to a wafer fabrication process. A cooling device may be installed around areas where hot spots may occur. The cooling device may include a device using the Peltier effect, such as a peltier cooler. Another cooling device may be a fixed or variable speed fan.

In accordance with the exemplary embodiments of the present invention, temperature sensors may be uniformly arranged over the entire surface of a semiconductor device. The temperature sensors may be selected in an address method by a matrix switch. A closed loop may be formed at the selected temperature sensor. Therefore, the temperature at the surface of a semiconductor device may be precisely measured.

The matrix switch may selectively output the output signal of the temperature sensors, thereby eliminating the need for complicated wiring.

A signal post-processing unit may filter, amplify, convert, and transmit the output signal output from the temperature sensor to a measuring unit. Therefore, the temperature at the temperature sensor may be precisely measured.

A temperature sensing unit may be installed in a small area, and may be applied to a semiconductor chip unit.

Furthermore, the fabricated semiconductor package may be designed for heat radiation using information on the surface temperature of its semiconductor chip.

Although exemplary, non-limiting embodiments of the present invention have been described in detail hereinabove, it should be understood that many variations and/or modifications of the basic inventive concepts herein taught, which may appear to those skilled in the art, will still fall within the spirit and scope of the exemplary embodiments of the present invention as defined in the appended claims.

What is claimed is:

1. A temperature measuring device comprising:
a semiconductor device;
temperature sensors arranged on a surface of the semiconductor device;
a matrix switch to select the temperature sensors by an address to form a circuit that includes the selected temperature sensor, and to output an output signal of the selected temperature sensor; and
a measuring unit to receive the output signal and to calculate the temperature at the selected temperature sensor.

2. The device of claim 1, wherein the temperature sensor includes:
a first metal wiring formed on the surface of the semiconductor device and being grounded, the first metal wiring having a connection projection;
an insulating layer formed on the first metal wiring such that the top of the connection projection is exposed; and
a second metal wiring formed on the insulating layer and having one portion connected to the connection projection and another portion connected to the matrix switch, the second metal wiring enabled to be opened and closed by the matrix switch.

3. The device of claim 1, wherein the matrix switch includes:
row switches to couple the temperature sensors to column lines, each row switch being in a corresponding row address line and being configured to be opened and closed by a row address signal; and
column switches configured to be opened and closed by a column address signal, the column switches to output the output signal of the selected temperature sensor in a corresponding column line.

4. The device of claim 3, further comprising a signal post-processing unit formed on the semiconductor device to convert the output signal of the selected temperature sensor to an output signal that can be processed by the measuring unit.

5. The device of claim 4, wherein the signal post-processing unit includes:
a filter to remove noise from the output signal of the selected temperature sensor;
an amplifier to amplify the output signal passed through the filter;
an analog/digital converter to convert the signal passed through the amplifier to a digital signal; and
a buffer to store the output signal.

6. The device of claim 4, further comprising a transmitter to transmit the output signal converted by the signal post-processing unit to the measuring unit.

7. The device of claim 6, wherein the transmitter transmits the output signal converted by the signal post-processing unit to the measuring unit through a wireless communication network.

8. The device of claim 1, wherein the measuring unit is a data acquisition system and is installed inside the semiconductor device.

9. The device of claim 1, wherein the measuring unit is a data acquisition system and is installed outside the semiconductor device.

10. The device of claim 1, wherein the semiconductor device includes a semiconductor chip or a wafer.

11. A device comprising:
a semiconductor chip having a temperature sensing unit; and
an external connection terminal electrically connected to the semiconductor chip and having a temperature output terminal to transmit an output signal output from the temperature sensing unit to outside the semiconductor chip,
wherein the temperature sensing unit includes a plurality of temperature sensors arranged on a surface of the semiconductor chip, and a matrix switch to select the temperature sensors by an address to form a closed loop that includes the selected temperature sensor, and to output an output signal of the selected temperature sensor to the temperature output terminal.

12. The device of claim 11 comprising:
a measuring unit to receive the output signal output from the selected temperature sensor to calculate the temperature at the temperature sensor; and
a controller to receive information about surface temperatures of the semiconductor chip, and to switch a specific area of the semiconductor chip to a sleep mode to cool the specific area if the surface temperature of the specific area is beyond a predetermined temperature.

13. The device of claim 12, further comprising a cooling device to cool the semiconductor package, the cooling device responsive to the controller.

14. The device of claim 13, wherein the cooling device is a peltier cooler.

15. The device of claim 13, wherein the cooling device is a variable speed fan.

16. A method of detecting temperatures of a semiconductor device comprising:
placing temperature sensors on a surface of the semiconductor device in a matrix configuration, each of the temperature sensors addressable by corresponding row and column addresses;
selectively connecting the temperature sensors using the row and column addresses to a measuring unit;
receiving output signals from the connected temperature sensors by the measuring unit;
converting the received output signals to temperature values; and
outputting the temperature values.

17. The method of claim 16, wherein the selectively connecting includes applying a row address signal to the gate of a first transistor and applying a column address signal to the gate of a second transistor.

18. The method of claim 17, wherein the temperature sensors operate using the Seebeck Effect.

19. The method of claim 18, wherein each temperature sensor comprises a first metal and a second metal different than the first metal, the first metal connected to an electrical ground and the second metal connected to the first transistor.

20. The method of claim 16, wherein a wireless transmitter intervenes between the temperature sensors and the measuring unit.
